(19) United States
(12) Patent Application Publication
(10) Pub. No.: US 2026/0293146 A1
(43) Pub. Date: Sep. 24, 2026

(54) FERROELECTRIC TRANSISTOR MEMORY STRUCTURE

(71) Applicant: GlobalFoundries Singapore Pte. Ltd., Singapore (SG)

(72) Inventors: Shyue Seng Tan, Singapore (SG); Kian Ming Ng, Singapore (SG); Eng Huat Toh, Singapore (SG)

(21) Appl. No.: 19/083,580

(22) Filed: Mar. 19, 2025

(51) Int. Cl. H10B 51/30

(52) U.S. Cl. CPC H10B 51/30

(57) ABSTRACT

The disclosure provides a structure with a ferroelectric material encompassing a gate structure, and methods to provide the same. A structure of the disclosure includes a gate structure over a substrate. Encompassing the gate structure is a ferroelectric material. On the ferroelectric material is an active semiconductor material connecting a first source/drain electrode to a second source/drain electrode.

### BACKGROUND

The present disclosure relates generally to integrated circuits, and more specifically, to memory structures.

In the field of integrated circuits (ICs), ferroelectric field effect transistors (FeFETs) are transistor structures similar to conventional FETs but include a gate stack with a ferroelectric material instead of a high dielectric constant (high-K) layer. The magnetic polarization of the ferroelectric material is retained regardless of whether the device is powered on or off, and thus the polarization can encode high or low memory states (i.e., a one or zero). The polarization can be changed by applying a voltage to the gate, making FeFETs desirable as single transistor non-volatile memory cells. Thus, in an array of FeFETs (where each transistor defines a respective cell), data may be programmed into each cell as a “one” or “zero” by selecting desired cells via a set of corresponding transistors and applying a programming voltage to the selected cells. Structural aspects of a FeFET (e.g., channel length, gate size, etc.) may affect the voltages needed to program or erase data thereon.

### SUMMARY

All aspects, examples and features mentioned below can be combined in any technically possible way.

An aspect of the disclosure is directed to a structure comprising: a gate structure on a substrate; a ferroelectric material encapsulating the gate structure; and an active semiconductor material on the ferroelectric material, connecting a first source/drain electrode to a second source/drain electrode.

An aspect of the disclosure provides a field-effect transistor (FET) comprising: a gate structure on a substrate; a ferroelectric material encapsulating the gate structure; and an active semiconductor material on the ferroelectric material, connecting a source electrode to a drain electrode wherein the active semiconductor material includes: a first portion having a first width between the ferroelectric material and the source electrode, and a second portion, adjacent the first portion, having a second width between the ferroelectric material and the drain region, wherein the second width is greater than the first

[symbol]

An aspect of the disclosure provides a method including: forming a gate structure over a substrate; encapsulating the gate structure in a ferroelectric material; and forming an active semiconductor material on the ferroelectric material, connecting a first source/drain electrode to a second source/drain electrode.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of an initial structure with a gate structure over a substrate, according to embodiments of the disclosure;

FIG. 2 shows a cross-sectional view of forming a ferroelectric material and an active semiconductor material, according to embodiments of the disclosure;

FIG. 3 shows a cross-sectional view of a structure according to embodiments of the disclosure;

FIG. 4 shows a cross-sectional view of a structure with an additional gate structure, according to embodiments of the disclosure;

FIG. 5 shows a cross-sectional view of a structure with an electrode covering the active semiconductor material, according to embodiments of the disclosure;

FIG. 6 shows a cross-sectional view of a structure with multiple bits per cell, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure with a Ferroelectric field-effect transistor (FeFET). The structure includes a gate structure encapsulated by a ferroelectric material and an active semiconductor material, connecting different source/drain electrodes. An embodiment of the structure includes FeFET structure over a substrate.

FIGS. 3-6 depict a structure 100, 200, 300 (particularly, a FeFET) for providing non-volatile memory by storing electrical data within a gate structure. Structure(s) 100, 200, 300 may include a semiconductor-on-insulator (SOI) structure, a bulk semiconductor structure, or other type of device architecture. In any case, structure(s) 100, 200, 300 include a first source/drain electrode 102, a second source/drain electrode 108, an active semiconductor material 116, a ferroelectric material 118 and a gate structure 120. During a write operation (i.e., storing of data in structure(s) 100, 200, 300), a specified voltage can be applied to gate structure 120 while transmitting current across first and second source/drain electrodes 102,108 (e.g., using gate voltage Vg). This may allow structure 100, 200, 300 to be programmed with a low threshold voltage (VT) (thereby storing a “1”) or erased so that it has a high VT (thereby storing a “0”). For example, to program an N-type FeFET (i.e., achieve a low VT and store a “1”), a positive voltage can be applied to gate structure 120 and first and second source/drain electrodes 102,108 can be connected to ground. As a result, the polarization vector in the ferroelectric material 118 is oriented towards the active semiconductor material 116, thereby attracting electrons into active semiconductor material 116 and reducing VT. To erase the N-type FeFET (i.e., achieve a high VT and store a “0” in the memory transistor 10), a negative voltage can be applied to gate structure 120 and first and second source/drain electrodes 102,108 can again be connected to ground. As a result, the direction of polarization vector in the ferroelectric material 118 is oriented away from active semiconductor material 116, thereby repelling electrons from active semiconductor material 116 and increasing VT. In other words, ferroelectric material 118 that encapsulates gate structure 120 is capable of having a positive (i.e., upward) oriented electric field or negative (i.e., downward) oriented electric field. Applying a gate voltage (Vg) to gate structure 120 of at least a threshold magnitude may cause ferroelectric material 118 within the gate 120 to switch positive or negative orientations (i.e., polarizations). Conventional memory transistor can only retain one logic level (and hence one binary digit or “bit”) at a time.

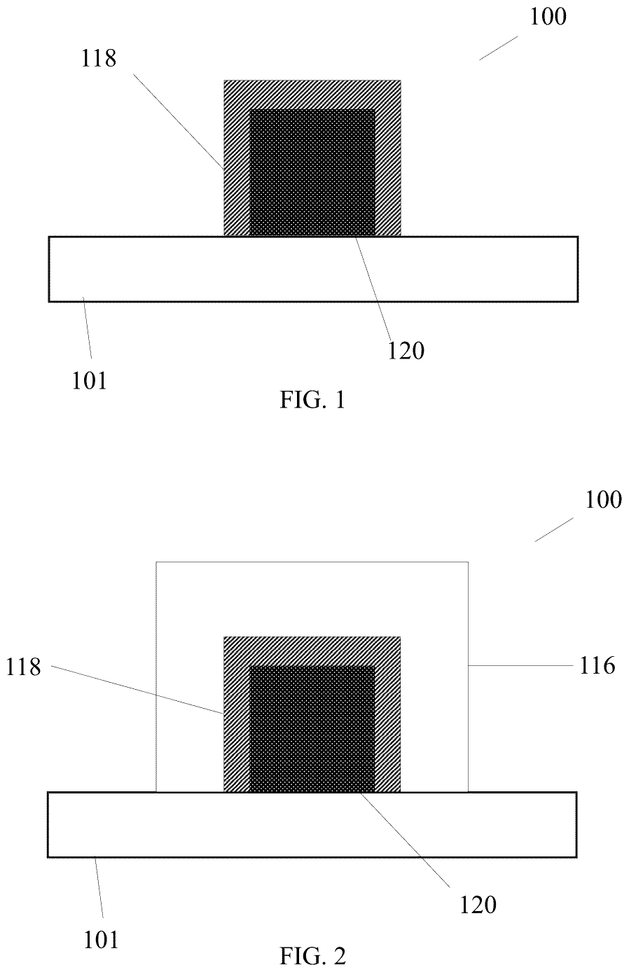

FIGS. 1-3 show cross-sectional views of a method of forming a structure(s) 100, 200, 300 (FIGS. 3-6) according to embodiments of the disclosure. As will be described and as shown in FIGS. 3-6, the method allows fabrication of structure(s) 100, 200, 300 with source/drain electrodes 102,108 in multiple configurations. As will be described, the method optionally allows fabrication of an additional gate structure 122 with gate structure 120, such that they may share substrate 101.

FIG. 1 shows a cross-sectional view of the fabrication of structure 100 (FIGS. 3-6) after a number of initial steps, including forming a gate structure 120 and a ferroelectric material 118, encapsulating gate structure 120. Structure 100 may be formed on a substrate 101, e.g., one or more semiconductor materials. Substrate 101 may include but is not limited to silicon, germanium, silicon germanium, silicon carbide, or any other common integrated circuit (IC) semiconductor substrates. Other substrates are also possible. Further, a portion or entire semiconductor substrate 101 may be strained. Substrate 101 is illustrated as a bulk semiconductor layer, but this is not required in all implementations. Various portions of substrate 101 may be doped with p-type and/or n-type dopants to provide a desired conductivity type.

As shown in FIG. 1, gate structure 120 may be formed over a portion of substrate 101. Gate structure 120 may be formed using any known or later developed semiconductor fabrication process. In some embodiments gate structure 120 may be multi-layered (e.g., a gate metal layer). In some embodiments ferroelectric material 118 may be deposited over gate structure 120 using any known or later developed semiconductor fabrication process. In some embodiments ferroelectric material 118 may encompass gate material 120. For example, ferroelectric material 118 may be deposited such as to cover 3 sides of gate structure 120, gate structure 120 having at least 4 sides. Ferroelectric material 118 may include any dielectric that remembers the electric field to which it has been exposed. Ferroelectric material 118 may include but is not limited to: aluminum scandium nitride, hafnium dioxide, hafnium-zirconium oxide, bismuth titanate, polyvinylidene fluoride, lead zirconate titanates (PZT) (e.g., Pb(ZrₓTi₁₋ₓ)O₃), Pb₁₋ₓLnₓTiO₃ (PLT) and related mixed zirconate/titanates (PLZT). An external electric field of at least a minimum voltage magnitude (i.e., a “switching voltage”) may be effective to reverse the orientation of the electric polarization in ferroelectric material 118. For instance, ferroelectric material 118 may include one or more materials having a switching voltage of four volts (V) may switch from a negative orientation to a positive orientation when electrically biased at +4.0 V or more and may switch from a positive orientation to a negative orientation when electrically biased at −4.0 V or less. Positive or negative biasing voltages having a magnitude that is less than the switching voltage may not affect the electric polarization in ferroelectric material 118.

FIG. 2 shows a cross-sectional view of forming an active semiconductor material 116 over ferroelectric material 118. Active semiconductor material 116 may be deposited over ferroelectric material 118 using any known or later developed semiconductor fabrication process. Active semiconductor material 116 may be an intrinsic channel region (i.e., an undoped channel region) or can be doped. For example, active semiconductor material 116 may a channel doped so as to have P-type conductivity at a relatively low conductivity level (i.e., a P-channel region.).

As shown in FIG. 3-6, first and second source/drain electrodes 102, 108 may form so as to be positioned in several ways. First and second source/drain electrodes 102,108 may be formed using any known or later developed semiconductor fabrication process. Although not shown in the drawings, it will be recognized that in some embodiments first and second source/drain electrodes 102,108 may be formed by depositing a polysilicon layer using any appropriate deposition technique, e.g., CVD, and may be doped or undoped. In said embodiment a mask may then be patterned for removing polysilicon layer, where desired, using an appropriate etching chemistry, e.g., a reactive ion etching (RIE), to form first and second source/drain electrodes 102,108. Any masks described herein may be removed using any known removal process appropriate for the mask material, e.g., a wet etch for hard nitride mask or an ashing process (oxygen dry strip process) for a soft resist-based mask. In some embodiments portions of polysilicon layer and/or substrate may be doped to form first and second source/drain electrodes 102,108 of the FeFET, e.g. 102 is a source region and 108 a drain region. The doping processes may include, for example, ion implantation or in-situ doping of semiconductor material. As these processes are well known, no further details are provided so the reader can focus on the salient aspects of the disclosure. First and second source/drain electrodes 102,108 are doped, electrically active regions that define opposite terminals for current flow. When structure 100 is electrically biased, components thereof (e.g. ferroelectric material 118 as discussed herein) may create an electric field through active semiconductor material 116 to influence its conductivity, thus enabling or preventing flow between first source/drain electrode 102 and second source/drain electrode 108. First and second source/drain electrodes 102,108 are doped with a dopant having a selected polarity for a respective transistor. An n-type transistor may include n-type dopants such as but not limited to: phosphorous (P), arsenic (As), antimony (Sb), and a p-type transistor may include p-type dopants such as but not limited to: boron (B), indium (In) and gallium (Ga). For example, in some embodiments structure 100, 200, 300 can be an N-type FeFET. In this case, first and second source/drain electrodes 102,108 can be doped so as to have N-type conductivity at a relatively high conductivity level.

FIG. 3 shows an embodiment of structure 100 including first shaped source/drain electrode 102 partially over active semiconductor material 116 and second source/drain electrode 108 over active semiconductor material 116. In some embodiments, as shown in FIG. 3, first source/drain electrode 102 may include a first portion 104 and a second portion 106. In some embodiments, first portion 104 is on an upper surface of active semiconductor material 116. The area of first portion 104 overlapping active semiconductor material 116 may defined as a first length L1. First length L1 may be short or long as possible to provide better interaction between the components of structure 100. Embodiments of first source/drain electrode 102 may further include second portion 106. Second portion 106 may be below first portion 104 and adjacent a sidewall of active semiconductor material 116. Active semiconductor material 116 spaces first source/drain electrode 102 from ferroelectric material 118 and may be as narrow as possible to provide better interaction between the components of structure 100. In some embodiments active semiconductor material 116 may have a first width W1 between ferroelectric material 118 and where semiconductor material 116 contacts first source/drain electrode 102. For example, first source/drain electrode 102 may be a source electrode containing a first portion 104 and a second portion 106, wherein the width of active semiconductor material 116 is consistent along the portion materially interfacing with first source/drain electrode 102.

As shown in FIG. 3, structure 100 may include forming second source/drain electrode 108. Second source/drain electrode 108 may be the same or different material as first source/drain electrode 102. In some embodiments second source/drain electrode 108 may have the same or different doping as first source/drain electrode 102. In some embodiments, including the one shown in FIG. 3, second source/drain electrode 108 may be over active semiconductor material 116 and spaced away from first source/drain electrode 108. Active semiconductor material 116 spaces second source/drain electrode 108 from ferroelectric material 118 and may be as narrow as possible to provide better interaction between the components of structure 100. In some embodiments active semiconductor material 116 may have a second width W2 between ferroelectric material 118 and where semiconductor material 116 contacts second source/drain electrode 108. Second width W2 may be different or the same as first width W1. For example, second source/drain electrode 108 may be a drain electrode wherein the width of active semiconductor material 116 is a second width W2, which is greater than first width W1, and consistent along the portion of active semiconductor material 116 materially interfacing with second source/drain electrode 108.

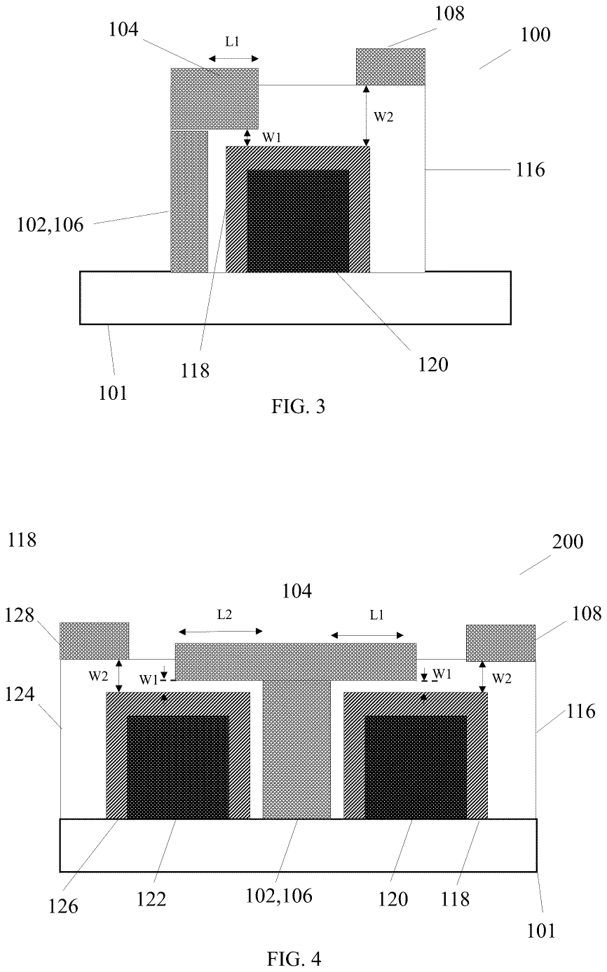

As shown in FIG. 4, structure 200 may include an additional gate structure 122, an additional active semiconductor material 124, an additional ferroelectric material 126, and an additional source/drain electrode 128. Additional gate structure 122 may be different or the same material as gate structure 120. Although not shown, it is understood that additional gate structure 122 may be formed at the same time as gate structure 120 using any known or later developed semiconductor fabrication process. Although embodiments of structure 100 are illustrated and described herein as having two gate structures 120, 122, it is understood that more than two gate structures may be provided in further implementations.

As shown in FIG. 4, structure 200 may further include forming an additional active semiconductor material 124 and additional ferroelectric material 126. Although not shown, it is understood that additional active semiconductor material 124 and additional ferroelectric material 126 may be formed at the same time as active semiconductor material 116 and ferroelectric material 118, respectively. Further, they may be using any known or later developed semiconductor fabrication process. In some embodiments, additional gate structure 122, an additional active semiconductor material 124, and an additional ferroelectric material 126 may be shaped similarly to active semiconductor material 116, ferroelectric material 118, and gate structure 120. For example, structure 200 may be mirrored about first source/drain electrode 102. In some embodiments, additional ferroelectric material 126 may have a difference in switching voltage with ferroelectric material 118. For instance, where ferroelectric material 118 has a switching voltage with a magnitude of approximately 4.0 V (whether positive or negative), additional ferroelectric material 126 may have a switching voltage with a magnitude of approximately 2.0 V. In further embodiments, these voltage magnitudes may be the opposite for each ferroelectric material 118, 126, and/or different values may be used.

In some embodiments, as shown in FIG. 4, first source/drain electrode 102 may include substantially vertical and substantially horizontal subsections and thus may be substantially “T” shaped. However implemented, first source/drain electric 102 may be horizontally between gate structure 120 and additional gate structure 122. First source/drain electrode 102 optionally may be shared between two individual transistors such that first source/drain electrode 102 collectively defines a pair of source terminals or a pair of drain terminals for the two different transistors. First source/drain electrode 102 thus may be considered part of the transistor that includes gate structure 120 and part of the transistor that includes additional gate structure 122. In some embodiments, first source/drain electrode 102 may include first portion 104 and second portion 106. In some embodiments, first portion 104 is on an upper surface of active semiconductor material 116 and on an upper surface of additional active semiconductor material 124. The area of first portion 104 overlapping additional active semiconductor material 124 may defined as a second length L2. Second length L2 may be different or the same length as first length L1 and as short or long as possible to provide better interaction between the components of structure 200. Embodiments of first source/drain electrode 102 may further include second portion 106. In some embodiments the width of additional active semiconductor material 124 between additional ferroelectric material 126 and where additional active semiconductor material 124 contacts first source/drain electrode 102, may be different or the same as first width W1.

FIG. 4 shows an embodiment of first source/drain electrode 102 having second portion 106 below first portion 104 and adjacent a sidewall of active semiconductor material 116 and a sidewall of additional active semiconductor material 124. For example, second portion 106 may be horizontally between active semiconductor material 116 and additional active semiconductor material 124.

Continuing with FIG. 4, some embodiments contain additional source/drain electrode 128. Although not shown, it is understood that additional source/drain electrode 128 may be formed at the same time as first source/drain electrode 102 and second source/drain electrode 108, using any known or later developed semiconductor fabrication process. In some embodiments additional source/drain electrode 128 may be the same doping as second source/drain electrode 108. In some embodiments, additional source/drain electrode 128 may be formed over additional active semiconductor material 124 and spaced away from first source/drain electrode 108. Active semiconductor material 124 may connect additional source/drain electrode 128 and first source/drain electrode 102. Active semiconductor material 124 be as narrow as possible to provide better interaction between the components of structure 100. In some embodiments, the width of additional active semiconductor material 124 between additional ferroelectric material 126 and where additional active semiconductor material 124 contacts additional source/drain electrode 128, may be different or the same as second width W2. For example, additional source/drain electrode 128 may be a drain electrode with the same doping as second source/drain electrode 108 and formed such that second source/drain electrode 108 is substantially mirrored (or otherwise similarly arranged) about first source/drain electrode 108. In this example, the width of additional active semiconductor material 124 and active semiconductor material 116 is second width W2, which is greater than first width W1, and consistent along the portion of additional active semiconductor material 124 and active semiconductor material 116 materially interfacing with additional source/drain electrode 128 and second source/drain electrode 108, respectively.

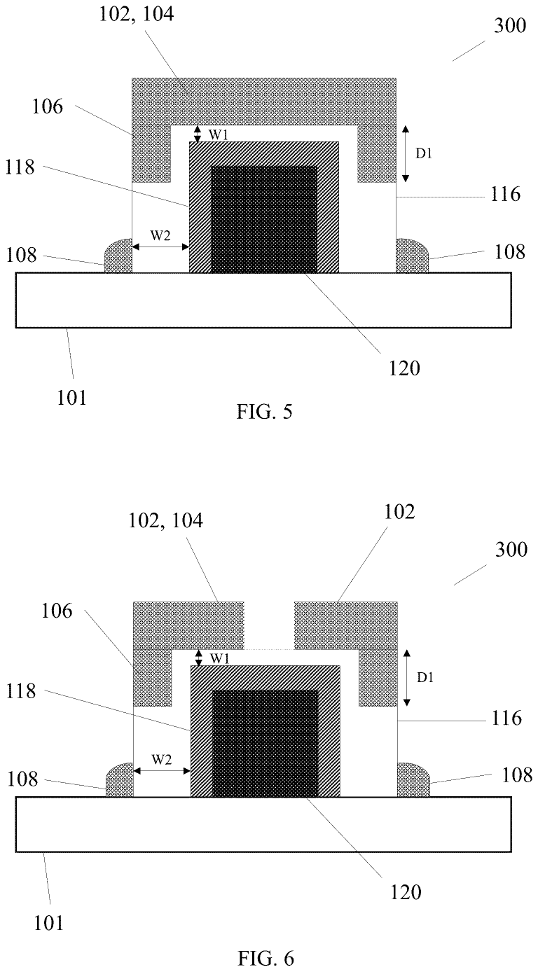

FIG. 5 shows a cross-sectional view of an embodiment including substrate 101, first source/drain electrode 102, second source/drain electrode 108, gate structure 120, active semiconductor material 116, and ferroelectric material 118. In some embodiments, as shown in FIG. 5, first source/drain electrode 102 may contact an upper surface of active semiconductor material 116. In some embodiments, first source/drain electrode 102 may include a first portion 104 and a second portion 106. In some embodiments, first portion 104 is on an upper surface of active semiconductor material 116. Embodiments of first source/drain electrode 102 may further include second portion 106. Second portion 106 may be below first portion 104, on an upper surface of a portion of active semiconductor material 116, and adjacent a sidewall of active semiconductor material 116. In some embodiments, a second portion 108 may be positioned on opposing ends of first portion 102. For example, a second portion 108 may be positioned below an end of first portion 102 and another second portion 108, positioned below an opposite end of first portion 102. In some embodiments active semiconductor material 116 may have first width W1 between ferroelectric material 118 and where semiconductor material 116 contacts first source/drain electrode 102. For example, first source/drain electrode 102 may be a source electrode containing a first portion 104 and two second portions 106, the portions 104, 106 over a top surface of active semiconductor material 116 substantially forming a substantial “n” shape. In said example the width of active semiconductor material 116 is consistent along the portion materially interfacing with first source/drain electrode 102.

As shown in FIG. 5, second source/drain electrode(s) 108 may be positioned below first source/drain electrode 102. In some embodiments, second source/drain electrode 108 is below first portion 104 of first source/drain electrode 102 and adjacent a sidewall of active semiconductor material 116. Second source/drain electrode 108 may also be formed in a variety of shapes and sizes e.g., quarter circle, square, etc. In some embodiments, structure 300 may include a plurality of second source/drain electrodes 108. For example, structure 300 may have two quarter circle second source/drain electrodes 108 acting as a drain on opposite sides of gate structure 120.

FIG. 6 shows a cross-sectional view of an embodiment of structure 300 including a plurality of first source/drain electrodes 102. In embodiments first source/drain electrodes 102 are on an upper surface of active semiconductor material 116 and spaced from each other. In some embodiments, structure 300 includes a plurality of first source/drain electrodes 102 and a plurality of second source/drain electrodes 108. In said embodiments, structure 300 may retain more than one logic level and hence multiple binary digits or “bits” at a time per transistor (i.e., per cell).

Embodiments of the disclosure provide various technical and commercial advantages, examples of which are discussed herein. The disclosure provides a structure and related method to provide an increased memory window and sensing margin by reducing the width of the active semiconductor material between the ferroelectric material and source/drain electrodes. In some embodiments of the disclosure memory window and sensing margin may also be increased by forming a source/drain electrode over an edge of ferroelectric material such that a portion of the source/drain electrode is over ferroelectric material and a portion is adjacent a sidewall. Further the disclosure provides a structure and related method to provide multiple bits of data in a relatively small surface area, i.e., by providing multiple source/drain electrodes per cell (FIG. 6) and/or by providing multiple FEFETs (FIG. 4). Providing multiple bits of data in a relatively small surface area therein may reduce the size of IC's incorporating said structure.

In the structures and method described above, a semiconductor material refers to a material whose conducting properties can be altered by doping with an impurity. Semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum, gallium, or indium, with group V elements, such as nitrogen, phosphorous, arsenic or antimony. A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron or indium, to achieve P-type conductivity, whereas a silicon-based semiconductor material is typically doped with a Group V dopant, such as arsenic (As), phosphorous or antimony, to achieve N-type conductivity. A gallium nitride-based semiconductor material is typically doped with magnesium to achieve P-type conductivity and with silicon or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The structure and method as described above are used in the fabrication of integrated circuit structures and/or chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a gate structure on a substrate;
a ferroelectric material encapsulating the gate structure; and
an active semiconductor material on the ferroelectric material, connecting a first source/drain electrode to a second source/drain electrode.

2. The structure of claim 1, wherein the second source/drain electrode is over the active semiconductor material.

3. The structure of claim 1, wherein the first source/drain electrode includes a first portion on an upper surface of the active semiconductor material and second portion below the first portion, adjacent a sidewall of the active semiconductor material.

4. The structure of claim 1, wherein the first source/drain electrode is substantially T-shaped and horizontally between the gate structure and an additional gate structure.

5. The structure of claim 4, wherein the first source/drain electrode includes a first portion on an upper surface of the active semiconductor material and on an upper surface of an additional semiconductor material.

6. The structure of claim 1, wherein the active semiconductor material includes:
a first portion having a first width between the ferroelectric material and the first source/drain electrode, and
a second portion, adjacent the first portion, having a second width between the ferroelectric material and the second source/drain electrode, wherein the second width is greater than the first width.

7. The structure of claim 1, wherein the first source/drain electrode contacts an upper surface of the active semiconductor material.

8. The structure of claim 7, wherein the first source/drain electrode is a source electrode and the second source/drain electrode is a drain electrode below the source electrode.

9. A field-effect transistor (FET) comprising:
a gate structure on a substrate;
a ferroelectric material encapsulating the gate structure; and
an active semiconductor material on the ferroelectric material, connecting a source electrode to a drain electrode
wherein the active semiconductor material includes:
a first portion having a first width between the ferroelectric material and the source electrode, and
a second portion, adjacent the first portion, having a second width between the ferroelectric material and the drain electrode, wherein the second width is greater than the first.

10. The structure of claim 9, wherein the drain electrode is over the active semiconductor material.

11. The structure of claim 9, wherein the source electrode includes a first portion on an upper surface of the active semiconductor material and second portion below the first portion, adjacent a sidewall of the active semiconductor material.

12. The structure of claim 9, wherein the source electrode is substantially T-shaped and horizontally between the gate structure and an additional gate structure.

13. The structure of claim 12, wherein the source electrode includes a first portion on an upper surface of the active semiconductor material and on an upper surface of an additional semiconductor material.

14. The structure of claim 9, wherein the source electrode contacts an upper surface of the active semiconductor material.

15. A method comprising:
forming a gate structure over a substrate;
encapsulating the gate structure in a ferroelectric material; and
forming an active semiconductor material on the ferroelectric material, connecting a first source/drain electrode to a second source/drain electrode.

16. The method of claim 15, wherein the second source/drain electrode is formed over the active semiconductor material.

17. The method of claim 15, wherein the first source/drain electrode includes a first portion on an upper surface of the active semiconductor material and second portion below the first portion, adjacent a sidewall of the active semiconductor material.

18. The method of claim 15, wherein the first source/drain electrode is substantially T-shaped and horizontally between the gate structure and an additional gate structure.

19. The method of claim 18, wherein the first source/drain electrode includes a first portion on an upper surface of the active semiconductor material and on an upper surface of an additional semiconductor material.

20. The method of claim 15, wherein forming the active semiconductor material includes:
forming a first portion having a first width between the ferroelectric material and the first source/drain electrode, and
forming a second portion, adjacent the first portion, having a second width between the ferroelectric material and the second source/drain electrode, wherein the second width is greater than the first.
